(19) United States
(12) Patent Application Publication
(10) Pub. No.: US 2007/0011507 A1
(43) Pub. Date: Jan. 11, 2007

(54) System and method for remote system support

(75) Inventors: Michael A. Rothman, Puyallup, WA (US); Vincent J. Zimmer, Federal Way, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/145,410

(22) Filed: Jun. 3, 2005

(51) Int. Cl. G11C 29/00

(52) U.S. Cl. 714/718

(57) ABSTRACT

In some embodiments, the invention involves a system and method relating to out-of-band debugging of a platform. In at least one embodiment, the present invention enables a debugger to operate during any operational phase of the platform. Specifically, the debugger may operate during pre-boot, before memory initialization and through to operating system load and execution. Other embodiments are described and claimed.

### FIELD OF THE INVENTION

An embodiment of the present invention relates generally to computing systems and, more specifically, to remote debugging tools.

### BACKGROUND INFORMATION

Various mechanisms exist for monitoring, controlling and managing a platform remotely. Existing servers may have an imbedded processor in addition to the main central processor. This additional processor is often a baseboard management controller (BMC). Some platforms may be equipped with Intel® Active Management Technology (IAMT). The BMC and IAMT will both typically have dedicated network interface cards (NICs) or the equivalent to enable out-of-band (OOB) communication with the platform.

The hardware enables one to communicate with the platform without interrupting the active processes. One issue with deployment of platforms is when an original equipment manufacturer (OEM) is charged with supporting the platform. In existing systems, this support is limited to providing very basic triage mechanisms through the operating system (OS) or possibly after-the-fact diagnostic utilities, such as a debug screen. The debug screen may give some information regarding what initiated the instability. If persistent hardware failures are common, the platform may have built in utilities, or a media disk used to execute debug code in an attempt to diagnose the hardware problem. These custom debuggers have been found to be insufficient, especially in high traffic business environments. For instance, in a banking environment with 20-30 teller machines all being used simultaneously, diagnosing which teller machine has a problem and determining the cause of the problem may be difficult or impossible.

For instance, suppose a user complains that one teller machine (randomly) hangs inexplicably about once per week. This may be unacceptable to the user, but extremely hard to diagnose, if not impossible. Duplicating this failure in a lab may not be possible because the traffic of data cannot be replicated, or is not sufficient to re-create the problem.

Instrumenting all of the customer's machines to diagnose in real time may be unfeasible, or impractical. Instrumenting typically comprises, hardware instrumentation with logic analyzers or in-target probes.

### BRIEF DESCRIPTION OF THE DRAWINGS

The features and advantages of the present invention will become apparent from the following detailed description of the present invention in which:

FIG. 1 is block diagram of an exemplary system topology illustrating an added network connection, according to an embodiment of the invention; and

FIGS. 2A-2C show flow diagrams illustrating methods to be performed by a platform infrastructure, a remote accessible debugger and an out-of-band microcontroller, according to an embodiment of the invention.

### DETAILED DESCRIPTION

An embodiment of the present invention is a system and method relating to out-of-band debugging of a platform. In at least one embodiment, the present invention is intended to enable a debugger to operate during any operational phase of the platform. Specifically, the debugger is intended to operate during pre-boot, before memory initialization and through to operating system load and execution (OS launch).

Reference in the specification to “one embodiment” or “an embodiment” of the present invention means that a particular feature, structure or characteristic described in connection with the embodiment is included in at least one embodiment of the present invention. Thus, the appearances of the phrase “in one embodiment” appearing in various places throughout the specification are not necessarily all referring to the same embodiment.

For purposes of explanation, specific configurations and details are set forth in order to provide a thorough understanding of the present invention. However, it will be apparent to one of ordinary skill in the art that embodiments of the present invention may be practiced without the specific details presented herein. Furthermore, well-known features may be omitted or simplified in order not to obscure the present invention. Various examples may be given throughout this description. These are merely descriptions of specific embodiments of the invention. The scope of the invention is not limited to the examples given.

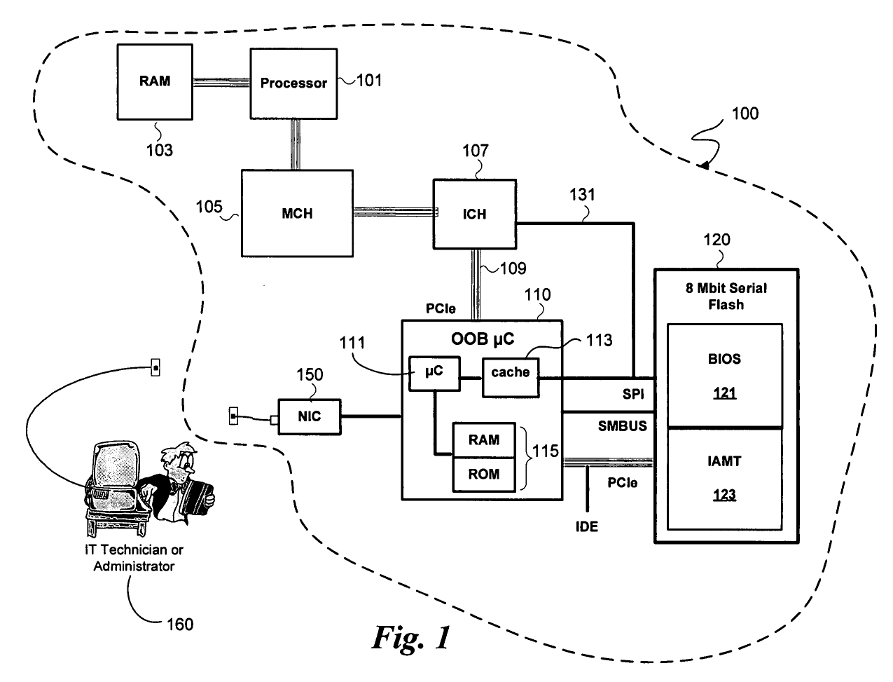

FIG. 1 is a block diagram illustrating features of an out-of-band microcontroller (OOB microcontroller), according to an embodiment of the environment. Embodiments of this system topology have an added network connection 150. NIC 150 may be used for OOB platform manageability. In an embodiment, the OOB microcontroller support is intended for managing the system without perturbing the performance of the system. Layered on top of this OOB infrastructure is a means to allow for remotely initiating a debugging session, or a “trace” session. If an existing platform experiences a system hang, not much can be done to diagnose the problem. If the monitor does not display an error message and the system was not instrumented to be traced, diagnosis is very difficult.

In an embodiment of the invention, if a platform hangs, the user or operator may contact a remote technician 160 to access a remote debugging session via the OOB microcontroller 110. Many hangs are not generated by hardware defects. A system hang is often the result of a software anomaly. The software anomaly is often caused by loading a software agent from a hard drive or other media or network. The problem may be within the OS, drivers or running application. Something in the software stack often caused the problem.

In embodiments of the invention, a user may give the remote technician 160 information to identify the system experiencing symptoms. The remote technician may be able to view the software stack remotely via the OOB connection to determine which application failed.

A platform 100 comprises a processor 101. The processor 101 may be connected to random access memory 103 via a memory controller hub 105. Processor 101 may be any type of processor capable of executing software, such as a microprocessor, digital signal processor, microcontroller, or the like. Though FIG. 1 shows only one such processor 101, there may be one or more processors in the platform 100 and one or more of the processors may include multiple threads, multiple cores, or the like.

The processor 101 may be further connected to I/O devices via an input/output controller hub (ICH) 107. The ICH may be coupled to various devices, such as a super I/O controller (SIO), keyboard controller (KBC), or trusted platform module (TPM) via a low pin count (LPC) bus (not shown). The SIO, for instance, may have access to floppy drives or industry standard architecture (ISA) devices (not shown). In an embodiment, the ICH 107 is coupled to non-volatile memory 120 via a serial peripheral interface (SPI) bus 131. The non-volatile memory 120 may be flash memory or static random access memory (SRAM), or the like. An out-of-band (OOB) microcontroller 110 may be present on the platform 100. The OOB microcontroller 110 may connect to the ICH 107 via a bus 109, typically a peripheral component interconnect (PCI) or PCI express (PCIe) bus. The OOB microcontroller 110 may also be coupled with the non-volatile memory store (NV store) 120 via the SPI bus 131. The NV store 120 may be flash memory or static RAM (SRAM), or the like. In many existing systems, the NV store is flash memory.

The OOB microcontroller 110 may be likened to a “miniature” processor. Like a full capability processor, the OOB microcontroller has a processor unit 111 which may be operatively coupled to a cache memory 113, as well as RAM and ROM memory 115. The OOB microcontroller may have a built-in network interface and independent connection to a power supply 150 to enable out-of-band communication even when the in-band processor 101 is not active.

In embodiments, the processor has a basic input output system (BIOS) 121 in the NV store 120. In other embodiments, the processor boots from a remote device (not shown) and the boot vector (pointer) resides in the BIOS portion 121 of the NV store 120. The OOB microcontroller 110 may have access to all of the contents of the NV store 120, including the BIOS portion 121 and a protected portion 123 of the non-volatile memory. In some embodiments, the protected portion 123 of memory may be secured with Intel® Active Management Technology (IAMT). More information about IAMT may be found on the public Internet at URL www-intel-com/technology/manage/iamt/. (Note that periods have been replaced with dashes in URLs contained within this document in order to avoid inadvertent hyperlinks).

The OOB microcontroller may be coupled to the platform to enable SMBUS commands. The OOB microcontroller may also be active on the PCIe bus. An integrated device electronics (IDE) bus may connect to the PCIe bus. In an embodiment, the SPI 131 is a serial interface used for the ICH 107 to communicate with the flash 120. The OOB microcontroller may also communicate to the flash via the SPI bus. In some embodiments, the OOB microcontroller may not have access to one of the SPI bus or other bus.

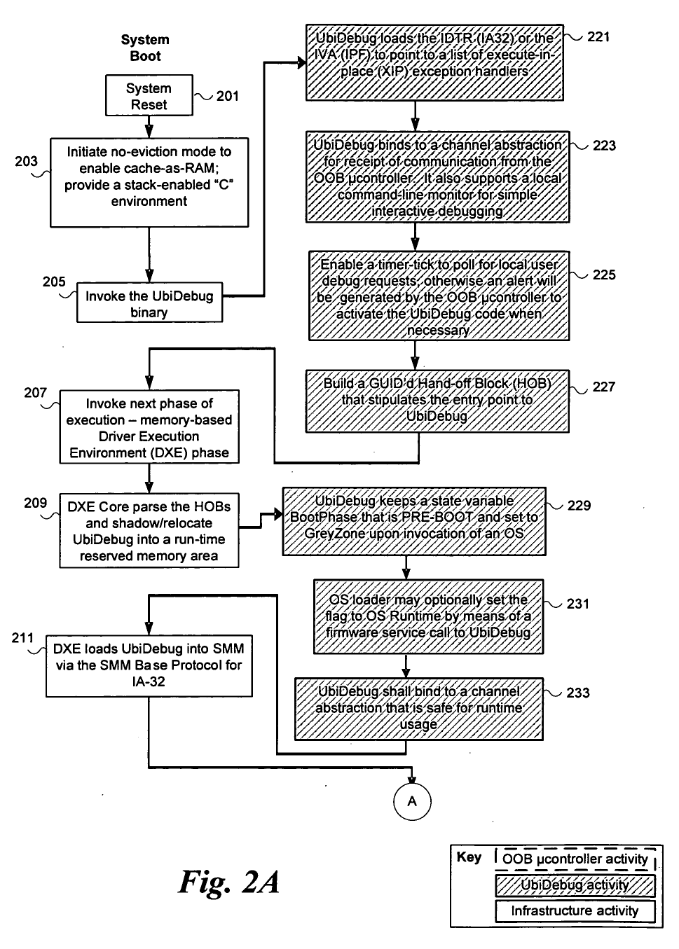

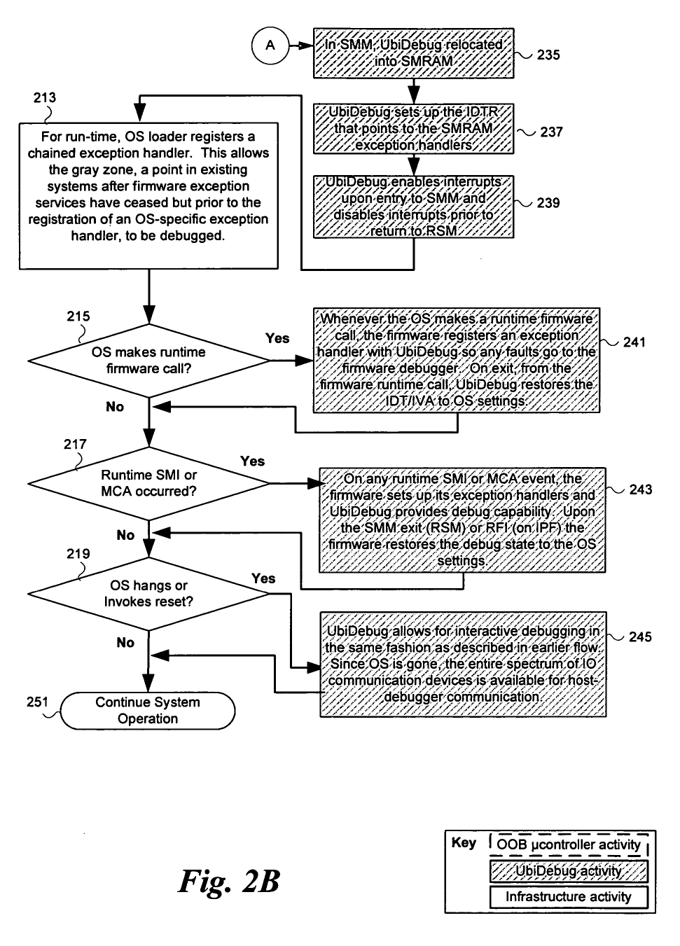

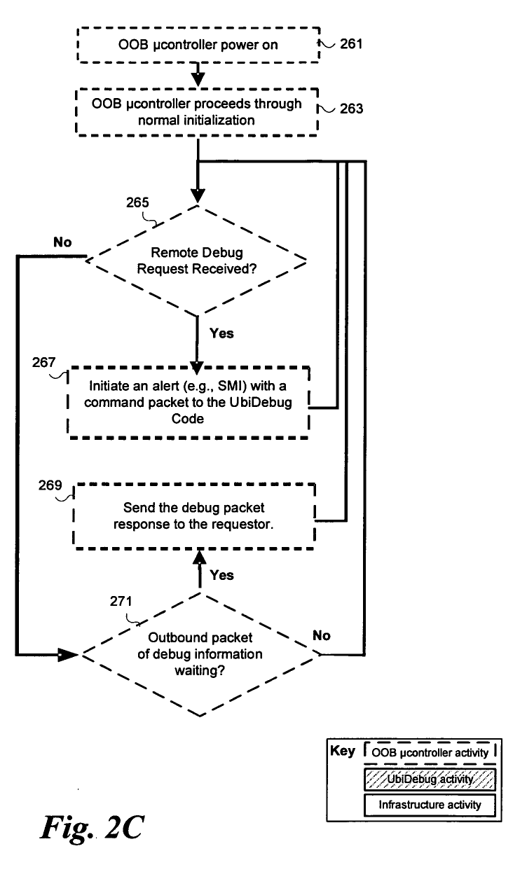

FIGS. 2A, 2B and 2C illustrate an exemplary process flow for the system infrastructure (clear boxes), debug activity (hatched box), and OOB μcontroller (dashed line box). To begin the process, the normal power-on routine is performed at system restart 201. Optionally, a no-eviction mode is initiated in 203 to enable cache-as RAM (CRAM) in a stack-enabled “C” environment. In older legacy systems, the BIOS was forced to run assembly language from the flash device (non-volatile memory). The code was primitive low level construction. Initialization had to be well under way before stack-based code could run during boot. Embodiments of the present invention enables debug activities to be performed closer in time to the reset vector (early on). Thus, if a crash/hang occurs early in power-on-self-test (POST), then a debug technician might be able to diagnose the problem remotely. No-eviction mode is a means by which software data may be put into a cache for later reference. No-eviction mode is a means by which higher level calling conventions, such as used with the C programming language, may be used early in the boot process, even before memory is initialized.

In existing systems, debug activities are typically limited to an OS-present model. When the OS is up and running, there may be system builds that are kernel debug enabled. These builds may allow a technician to perform some remote debugging. However, the remote debugger is dependent on the OS still operating. If the OS goes down, the remote debugger will not operate. Embodiments of the present invention are independent of the OS.

The debugger binary may now be invoked in 205. The binary may be a component residing in flash memory. The debugger binary may be considered to be execute-in-place (XIP). XIP code may be necessary if system memory has not yet been initialized. The XIP is not a standard executable with segments associated with system memory mapping. It will likely run directly from the flash memory.

In an embodiment using IA-32 architecture, the debugger code loads the Interrupt Description Table Register (IDTR) to point to a list of execute-in-place (XIP) exception handlers in block 221. Other architectures, for instance, the Itanium® processor family (IPF), may implement this function by pointing an interrupt vector address to the XIP exception handlers. It will be apparent to those of ordinary skill in the art that other methods of referencing the handlers is possible, based on the platform architecture. If an exception is needed, for instance to alert the debugger to wake up and perform an operation, the exception handlers are to be executed. The exception handlers may be located where the flash device was mapped into an address location. There may not be memory at this location, but the flash is mapped to this location.

In an embodiment, the debugger binds to a channel abstraction for receipt of communication from an out-of-band (OOB) microcontroller. The debugger may also support a local command-line monitor for simple interactive debugging in block 223. The debugger waits to receive communication from a remote technician via the OOB. The debugger may respond to a remote request via the OOB connection, as well. Often, communications between the debugger and the OOB network interface utilize the peripheral component interconnect (PCI) or PCI express (PCIe) bus. The OOB microcontroller typically has a dedicated network controller for communication with the remote technician. The debugger communicates with the OOB microcontroller which acts as a proxy for communication with the remote technician. The channel abstraction merely indicates that a channel between the debugger and the remote technician is opened. While some embodiments use the PCI bus for communication to the OOB microcontroller, it will be apparent to one of ordinary skill in the art that other buses may be used instead.

In block 225, a timer-tick may be enabled to poll for local user debug requests. This may be implemented as a watchdog timer, or similar. If the timer times out, an alert may be generated by the OOB microcontroller to activate the debugger code. In an embodiment, if the system hangs up, even during boot, then the timer will time out and the OOB microcontroller alerts the debugger to debug the problem.

The debugger may build a globally unique identifier (GUID) hand off block (HOB) that stipulates the entry point into the debugger, in block 227. The debugger is now initialized and waits for instruction. Control may pass to the debugger via exception handling, as will be discussed below.

The system then invokes the next phase of execution, i.e., memory-based driver execution environment (DXE) phase in block 207. The DXE core may parse the HOBs and then shadow, or relocate, the debugger code to run-time reserved memory area in block 209. When relocated, the debugger is typically put under system management mode (SMM).

In block 229 the debugger may keep a state variable, for instance, BootPhase, that is set to “PRE-BOOT” during pre-boot phases and set to “GreyZone” when the Operating System (OS) invoked, but perhaps not yet running. The OS loader may optionally set the state variable to “OS RUNTIME” by means of a firmware service call to the debugger, once it is running, in block 231.

During pre-boot, the debugger has many options for communication channels. In some embodiments, when the OS is running, these choices may be more limited, as the OS may need exclusive control of certain channels. Thus, the debugger may bind to a channel abstraction that is safe for runtime usage in block 233. In other embodiments, the channel to the OOB microcontroller is not exposed to the OS, so the previously bound channel may continue to be used.

In some embodiments, prior to running the OS, the system (DXE phase) may load the debugger into SMM via the SMM Base Protocol for IA-32 in block 211. The debugger currently residing in runtime memory is thus made more secure since the SMM state is opaque to the OS.

The debugger may be relocated into SMRAM associated with SMM, in block 235. It should be noted that the debugger may be run prior to being located in SMRAM by executing the XIP code in flash. Once relocated, the debugger may set the IDTR to point to the SMRAM exception handlers in block 237. The debugger will enable interrupts upon entry to SMM and disables interrupts prior to resume from SSM mode (RSM) in block 239. The debugger may now be operated, when necessary, until system power down.

The OS loader may register a chained exception handler in block 213. This allows the gray zone to be debugged, i.e., the point at which the firmware exception services have ceased, but prior to registration of OS-specific exception handlers.

At this point, the OS is running and the debugger waits for instructions or an exception. If the OS makes a runtime firmware call, as determined in block 215, the firmware may register an exception handler with the debugger in block 241. Thus, any faults will transfer control to the debugger. On exit from the firmware runtime call, the debugger may restore the interrupt description tables (IDT) or interrupt vector addresses (IVA) to the OS settings.

If a runtime system management interrupt (SMI) or machine check architecture event occurred, as determined in block 217, the firmware may set up exception handlers in block 243 and the debugger provides debug capability. Upon the SMM exit (RSM) or return from interrupt (RFI) for the Itanium® processor family (IPF), the firmware restores the debug state to the OS settings.

If the OS has hung up or invoked a reset, as determined in block 219, the debugger may allow for interactive debugging, as discussed above, in block 245. In one embodiment, a system hang may be identified by the expiration of the watchdog timer. Since the OS is no longer functioning, the entire spectrum of input/output (I/O) communication devices is available for host-debugger communication.

FIG. 2C is a block flow diagram illustrating the activities of an out-of-band (OOB) microcontroller using an embodiment of the above disclosed debugger. At system power on, the OOB microcontroller is powered on at 261. In some embodiments, the OOB is powered on upon access to an electrical source, and functions before the main system is powered on. The OOB microcontroller typically has its own processor, so when powered on the microcontroller proceeds through initialization as would any other processor, in block 263. The OOB microcontroller may be involved with many tasks that are unrelated to the debugging process. For instance, the OOB microcontroller may be used for server management tasks and forward status information to a remote technician.

When the OOB microcontroller receives a remote debug request from a technician or remote system, as determined in block 265, an alert may be initiated (e.g., an SMI) with a command packet to the debugger, in block 267. The OOB microcontroller then continues to wait for additional debug requests.

When the OOB microcontroller receives notification that an outbound packet of debug information is waiting to be sent, as determined in block 271, the OOB microcontroller sends the outbound packet response to the requestor in block 269.

Because the OOB microcontroller may enable several processes to communicate to remote technicians or systems, it may be busy with another process when debug requests or responses arrive. It will be apparent to one of ordinary skill in the art that various methods may be used to identify and buffer debug packets of information and interleave activities for various processes.

In some embodiments, the OOB microcontroller may comprise a baseboard management controller (BMC). In other embodiments, the OOB microcontroller may comprise Intel Active Management Technology.

The techniques described herein are not limited to any particular hardware or software configuration; they may find applicability in any computing, consumer electronics, or processing environment. The techniques may be implemented in hardware, software, or a combination of the two. The techniques may be implemented in programs executing on programmable machines such as mobile or stationary computers, personal digital assistants, set top boxes, cellular telephones and pagers, consumer electronics devices (including DVD players, personal video recorders, personal video players, satellite receivers, stereo receivers, cable TV receivers), and other electronic devices, that may include a processor, a storage medium accessible by the processor (including volatile and non-volatile memory and/or storage elements), at least one input device, and one or more output devices. Program code is applied to the data entered using the input device to perform the functions described and to generate output information. The output information may be applied to one or more output devices. One of ordinary skill in the art may appreciate that the invention can be practiced with various system configurations, including multiprocessor systems, minicomputers, mainframe computers, independent consumer electronics devices, and the like. The invention can also be practiced in distributed computing environments where tasks or portions thereof may be performed by remote processing devices that are linked through a communications network.

Each program may be implemented in a high level procedural or object oriented programming language to communicate with a processing system. However, programs may be implemented in assembly or machine language, if desired. In any case, the language may be compiled or interpreted.

Program instructions may be used to cause a general-purpose or special-purpose processing system that is programmed with the instructions to perform the operations described herein. Alternatively, the operations may be performed by specific hardware components that contain hardwired logic for performing the operations, or by any combination of programmed computer components and custom hardware components. The methods described herein may be provided as a computer program product that may include a machine accessible medium having stored thereon instructions that may be used to program a processing system or other electronic device to perform the methods. The term “machine accessible medium” used herein shall include any medium that is capable of storing or encoding a sequence of instructions for execution by the machine and that cause the machine to perform any one of the methods described herein. The term “machine accessible medium” shall accordingly include, but not be limited to, solid-state memories, optical and magnetic disks, and a carrier wave that encodes a data signal. Furthermore, it is common in the art to speak of software, in one form or another (e.g., program, procedure, process, application, module, logic, and so on) as taking an action or causing a result. Such expressions are merely a shorthand way of stating the execution of the software by a processing system cause the processor to perform an action of produce a result.

While this invention has been described with reference to illustrative embodiments, this description is not intended to be construed in a limiting sense. Various modifications of the illustrative embodiments, as well as other embodiments of the invention, which are apparent to persons skilled in the art to which the invention pertains are deemed to lie within the spirit and scope of the invention.

What is claimed is:

1. A system, comprising:
a processor coupled to both system memory and non-volatile memory,
an out-of-band (OOB) processor communicatively coupled to the processor, the OOB processor having a dedicated network interface to communicate with a remote system;
a debugger module, the debugger module residing in the non-volatile memory before system memory initialization during pre-boot, the debugger to communicate with the remote system via the OOB processor during both pre-boot and after operating system (OS) launch.

2. The system as recited in claim 1, wherein the debugger comprises execute-in-place (XIP) instructions when residing in non-volatile memory.

3. The system as recited in claim 1, further comprising a basic input output system (BIOS) having firmware services and residing in the non-volatile memory, wherein firmware services are accessible to the debugger during pre-boot and after OS launch.

4. The system as recited in claim 1, wherein the debugger runs as XIP instructions before system memory is initialized during pre-boot.

5. The system as recited in claim 1, wherein the OOB processor is to receive requests from the remote system, the requests to initiate a debugging session using the debugger, and wherein results from the debugging session are to be sent to the remote system via the OOB processor.

6. The system as recited in claim 5, wherein the OOB processor is to trigger an alert to the debugger in response to a remote request to initiate a debugging session.

7. The system as recited in claim 6, further comprising at least one exception handler residing in memory, the at least one exception handler to initiate a debugging session when a fault occurs during execution, wherein the at least one exception handler resides in at least one of non-volatile memory or system memory.

8. A method, comprising:
initiating a boot phase of a platform having a system processor and an out-of-band (OOB) processor;
invoking a debugger as execute-in-place (XIP) in firmware coupled to the system processor; and
running a debugging session using the XIP debugger in response to one of an alert triggered by the OOB processor or a system failure during boot, wherein the OOB processor triggers an alert in response to a remote request.

9. The method as recited in claim 8, wherein the firmware is coupled to both the system processor and to the OOB processor.

10. The method as recited in claim 8, further comprising:
initializing system memory;
relocating the debugger into system memory; and
running a debugging session using the debugger in system memory, in response to one of an alert triggered by the OOB processor or a system failure during boot, wherein the OOB processor triggers an alert in response to a remote request.

11. The method as recited in claim 8, further comprising:
binding a communication channel abstraction, by the debugger, for receipt of communication from OOB processor.

12. The method as recited in claim 8, further comprising:
enabling a timer to poll for local user debug requests; and
initiating a local debugging session upon expiration of the timer.

13. The method as recited in claim 8, further comprising:
registering an exception handler to handle faults occurring in a firmware service; and
upon execution of the exception handler due to a fault in a firmware service, invoking the debugger, wherein the debugger runs in XIP mode prior to system memory initialization.

14. The method as recited in claim 8, wherein invoking the debugger precedes initialization of system memory.

15. A machine accessible medium having instructions that when executed cause the machine to:
in response to one of an alert triggered by an out-of-band (OOB) processor or a system failure during boot, wherein the OOB processor triggers an alert in response to a remote request, run a debugging session using a debugger coupled to a system processor, wherein the debugger resides as execute-in-place firmware during pre-boot, prior to initialization of system memory.

16. The medium as recited in claim 15, further comprising instructions that when executed cause the machine to:
initialize system memory;
relocate the debugger into system memory; and
run a debugging session using the debugger in system memory, in response to one of an alert triggered by the OOB processor or a system failure during boot, wherein the OOB processor triggers an alert in response to a remote request.

17. The medium as recited in claim 15, further comprising instructions that when executed cause the machine to:
bind a communication channel abstraction, by the debugger, for receipt of communication from OOB processor.

18. The medium as recited in claim 15, further comprising instructions that when executed cause the machine to:
enable a timer to poll for local user debug requests; and
initiate a local debugging session upon expiration of the timer.

19. The medium as recited in claim 15, further comprising instructions that when executed cause the machine to:
register an exception handler to handle faults occurring in a firmware service; and
upon execution of the exception handler due to a fault in a firmware service, invoke the debugger, wherein the debugger runs in XIP mode prior to system memory initialization.

20. The medium as recited in claim 15, wherein invoking the debugger precedes initialization of system memory.
